(19) United States
(12) Patent Application Publication
(10) Pub. No.: US 2013/0009286 A1
(43) Pub. Date: Jan. 10, 2013

(54) SEMICONDUCTOR CHIP AND FLIP-CHIP PACKAGE COMPRISING THE SAME

(75) Inventors: Young-lyong Kim, Gunpo-si (KR); Jong-ho Lee, Hwaseong-si (KR); Moon-gi Cho, Suwon-si (KR); Hwan-sik Lim, Gunpo-si (KR); Sun-hee Park, Seoul (KR)

(73) Assignee: SAMSUNG ELECTRONICS CO., LTD., Suwon-si (KR)

(21) Appl. No.: 13/471,735

(22) Filed: May 15, 2012

(30) Foreign Application Priority Data
Jul. 4, 2011 (KR) 10-2011-0066128

(51) Int. Cl. H01L 23/58

(52) U.S. Cl. 257/632; 257/E23.002

(57) ABSTRACT

A semiconductor chip includes stress-relief to mitigate the effects of differences in coefficients of thermal expansion (CTE) between a printed circuit board (PCB) and a semiconductor chip and a flip-chip package including the semiconductor chip. The semiconductor chip includes a stress-relief buffer coupling a bump and a semiconductor chip pad.

### CROSS-REFERENCE TO RELATED APPLICATIONS

This application claims the benefit of Korean Patent Application No. 10-2011-0066128, filed on Jul. 4, 2011, in the Korean Intellectual Property Office, the disclosure of which is incorporated herein in its entirety by reference.

### BACKGROUND

Exemplary embodiments in accordance with the principles of inventive concepts relate to a semiconductor device and a method of manufacturing the same, and more particularly, to a semiconductor chip comprising a bump structure, a flip-chip package containing the semiconductor chip, and a method of manufacturing the flip-chip package.

In general, a semiconductor package may be manufactured by performing a packaging operation to house semiconductor chips that are manufactured by performing various semiconductor processes on a wafer. A semiconductor package may include a semiconductor chip, a printed circuit board (PCB) on which the semiconductor chip is mounted, a bonding wire or bump that electrically connects the semiconductor chip and the PCB, and an encapsulation member that encapsulates the semiconductor chip. Due to the high integration degree of packages, reliability is required in terms of attaching the semiconductor chip to the PCB.

### SUMMARY

In exemplary embodiments in accordance with principles of inventive concepts a semiconductor chip in which a stress applied to pads due to a difference in coefficients of thermal expansion (CTE) of a printed circuit board (PCB) and the semiconductor chip includes stress-relief. A flip-chip package may include the semiconductor chip.

Exemplary embodiments in accordance with principles of inventive concepts provide a semiconductor chip, wherein a pad may be arranged on any position of the semiconductor chip, and a flip-chip package including the semiconductor chip.

In exemplary embodiments in accordance with principles of inventive concepts a semiconductor chip may be provided, in which a pad size may be reduced and a measure of freedom in terms of arranging a bump may be provided, and a flip-chip package including the semiconductor chip.

In exemplary embodiments in accordance with principles of inventive concepts, there is provided a semiconductor chip comprising: a body portion inside which wiring lines are formed; a pad that is formed on the body portion and is electrically connected to the wiring lines; a passivation layer covering the body portion and the pad and having an opening exposing a portion of the pad; a buffer disposed within the opening and that mitigates a stress applied to the pad; and a bump that is formed to cover the buffer and is electrically connected to the pad.

In exemplary embodiments in accordance with principles of inventive concepts, the buffer may include a conductive material or an insulating material and the bump may be extended to the passivation layer around the opening.

In exemplary embodiments in accordance with principles of inventive concepts a semiconductor chip may further include an under bump metal (UBM) that surrounds the buffer and is positioned between the bump and the passivation layer. The semiconductor chip may further include a UBM formed on the pad, wherein a side of the bump and the UBM are on the same plane.

In exemplary embodiments in accordance with principles of inventive concepts, the buffer may be formed either only within the opening or formed inside the opening and on portions of the passivation layer around the opening. The buffer may include one of a first type buffer having a concave portion corresponding to the opening, a second type buffer having a flat upper surface, and a third type buffer having an upper surface protruding in an upward direction. A protruding portion of the third type buffer may be vertical to or inclined with respect to a horizontal surface.

In exemplary embodiments in accordance with principles of inventive concepts the body portion may include an uppermost wiring layer disposed below the pad, and the pad may be electrically connected to the uppermost wiring layer through a via contact. The pad may be disposed at any position on the body portion.

In exemplary embodiments in accordance with principles of inventive concepts, there is provided a flip-chip package comprising: a main board in which a circuit pattern is formed; a semiconductor chip of that is mounted on a first surface of the main board in a flip-chip bonding method; an encapsulation member encapsulating the semiconductor chip; and an external connection terminal formed on a second surface of the main board which is opposite to the first surface of the main board.

In exemplary embodiments in accordance with principles of inventive concepts, there is provided a flip-chip package comprising: a semiconductor chip comprising a pad, wherein a portion of the pad is exposed via an opening of a passivation layer; a bump structure comprising a buffer that mitigates a stress applied to the pad, wherein the bump structure is formed on the pad and on the passivation layer around the opening; a main board in which a circuit pattern is formed, wherein the semiconductor chip is mounted on a first surface of the main board via the bump structure in a flip-chip bonding method; an encapsulation member encapsulating the semiconductor chip; and a connection terminal that is formed on a second surface of the main board which is opposite to the first surface of the main board.

In exemplary embodiments in accordance with principles of inventive concepts a semiconductor chip includes a body portion inside which wiring lines are formed; a pad that is formed on the body portion and is electrically connected to the wiring lines; a passivation layer covering the body portion and the pad, the passivation layer having an opening exposing at least a part of the pad; a stress-relief buffer disposed in the opening; and under-bump metal positioned between the buffer and the pad to link a pad and bump of different cross-sections.

In exemplary embodiments in accordance with principles of inventive concepts a wiring line is connected to a pad through a vertical via

In exemplary embodiments in accordance with principles of inventive concepts a lower surface of a pad contacts a rewiring line that contacts a wiring line.

In exemplary embodiments in accordance with principles of inventive concepts pad is located within a connection area of the chip.

In exemplary embodiments in accordance with principles of inventive concepts a pad is located in a main area of the chip.

### BRIEF DESCRIPTION OF THE DRAWINGS

Exemplary embodiments of the inventive concept will be more clearly understood from the following detailed description taken in conjunction with the accompanying drawings in which:

FIG. 1 is a perspective view illustrating a semiconductor chip in accordance with principles of inventive concepts;

FIG. 2 is a perspective view illustrating a semiconductor chip according to an exemplary embodiment in accordance with principles of inventive concepts;

FIG. 3 is a cross-sectional view illustrating a semiconductor chip illustrating an exemplary embodiment of a bump structure in accordance with principles of inventive concepts illustrated in FIG. 1 or FIG. 2;

FIGS. 4 through 10 are cross-sectional views illustrating modification examples of the semiconductor chip of FIG. 3, according to exemplary embodiments in accordance with principles of inventive concepts ;

FIGS. 11A through 11H are cross-sectional views illustrating a method of manufacturing the semiconductor chip of FIG. 3, in accordance with principles of inventive concepts;

FIG. 12 is a cross-sectional view illustrating a flip-chip package in accordance with principles of inventive concepts;

FIG. 13 is a block diagram of a memory card including a flip-chip package in accordance with principles of inventive concepts;

FIG. 14 is a block diagram of an electronic system including a flip-chip package in accordance with principles of inventive concepts;

FIG. 15 is a block diagram of an electronic device to which a flip-chip package in accordance with principles of inventive concepts may be applied.

### DETAILED DESCRIPTION OF THE EMBODIMENTS

Exemplary embodiments of the inventive concepts will now be described more fully with reference to the accompanying drawings, in which exemplary embodiments of the inventive concept are shown. Exemplary embodiments of the inventive concept may, however, be embodied in many different forms and should not be construed as limited to the embodiments set forth herein; rather, these exemplary embodiments of the inventive concept are provided so that this description will be thorough and complete, and will fully convey the concept of exemplary embodiments of the inventive concept to those of ordinary skill in the art. In the drawings, the thicknesses of layers and regions are exaggerated for clarity. Like reference numerals in the drawings denote like elements, and thus their description will be omitted.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated, for example, 90 degrees or at other orientations) and the spatially relative descriptors used herein interpreted accordingly.

The terminology used herein is for the purpose of describing particular exemplary embodiments of the inventive concept only and is not intended to be limiting of the inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the inventive concept are described herein with reference to cross-sectional illustrations that are schematic illustrations of idealized exemplary embodiments of the inventive concept (and intermediate structures). As such, variations from the shapes of the illustrations as a result, for example, of manufacturing techniques and/or tolerances, are to be expected. Thus, exemplary embodiments of the inventive concept should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

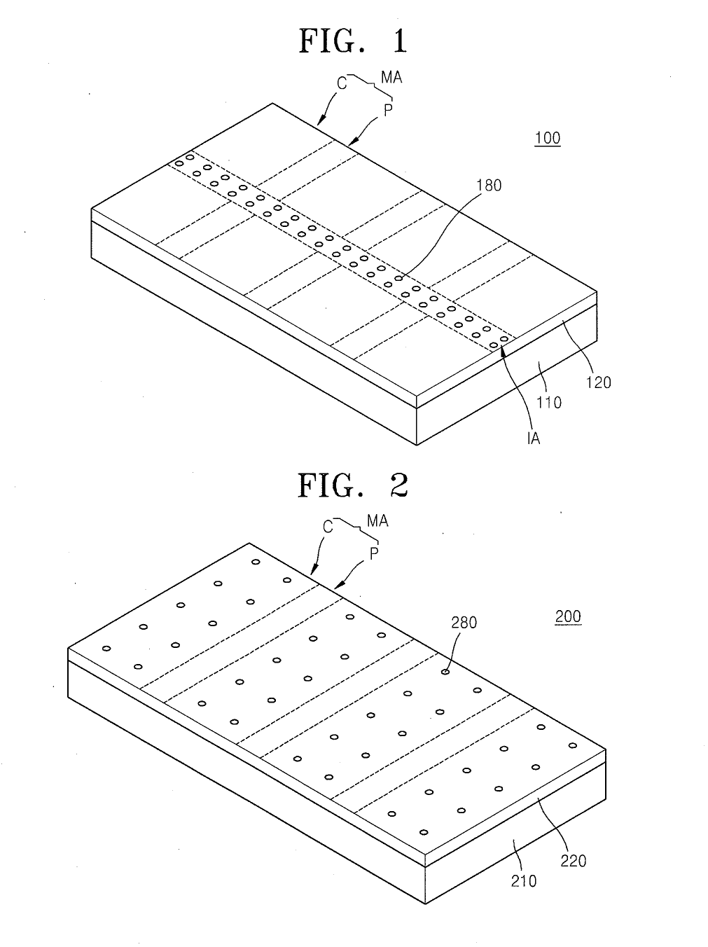

FIG. 1 is a perspective view illustrating a semiconductor chip 100 according to an exemplary embodiment in accordance with principles of inventive concepts. Semiconductor chip 100 may include a body portion 110, a passivation layer 120, and a bump structure 180.

Body portion 110 may include a plurality of semiconductor structures (not shown) stacked on a substrate, and wiring lines (not shown) that are electrically connected to the semiconductor structures. For example, the semiconductor structures, which may be memory or logic devices, may be stacked on a semiconductor substrate such as a wafer in a semiconductor device manufacturing process. Memory device may include a dynamic random access memory (DRAM), a static random access memory (SRAM), a flash memory, an electrically erasable programmable read-only memory (EEPROM), phase-change random access memory (PRAM), magnetoresistive random access memory (MRAM), or a resistive random access memory (RRAM), for example.

The wiring lines may be arranged on the semiconductor structures, and an interlayer insulating layer (not shown) may be interposed between the wiring lines and the semiconductor structures. The wiring lines may include a metal contact or a via contact that passes through the interlayer insulating layer to contact the semiconductor structures, and a metal wiring that is connected to the metal contact and disposed on the interlayer insulating layer. The wiring lines may be not only signal lines for transmitting an input/output signal but also a power line for supplying a power to the semiconductor structures or a ground line for grounding the semiconductor structures, for example.

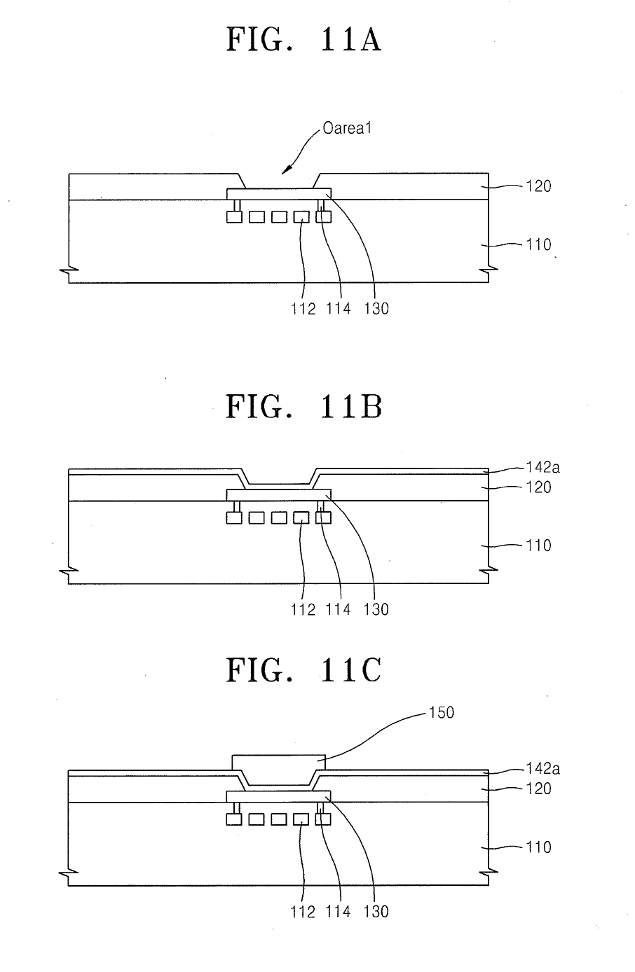

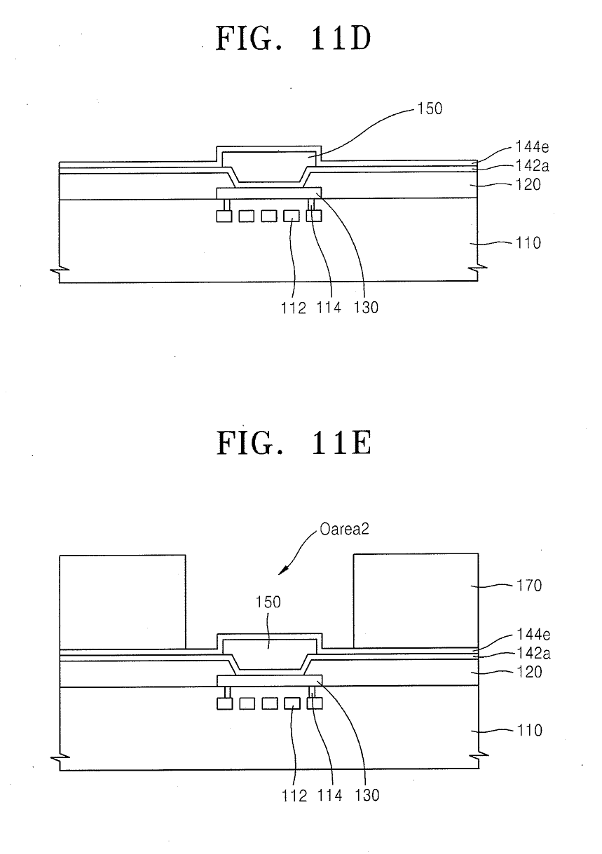

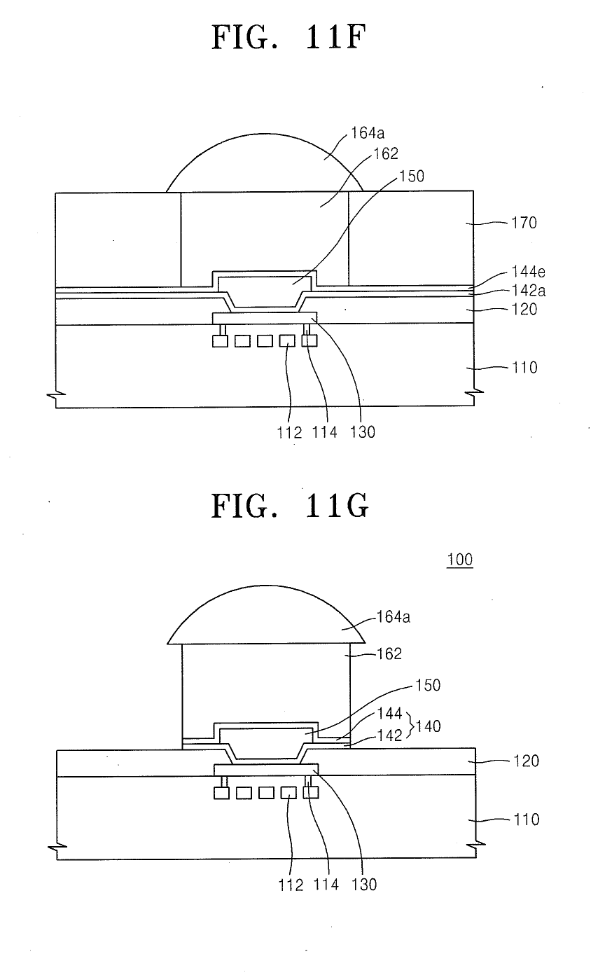

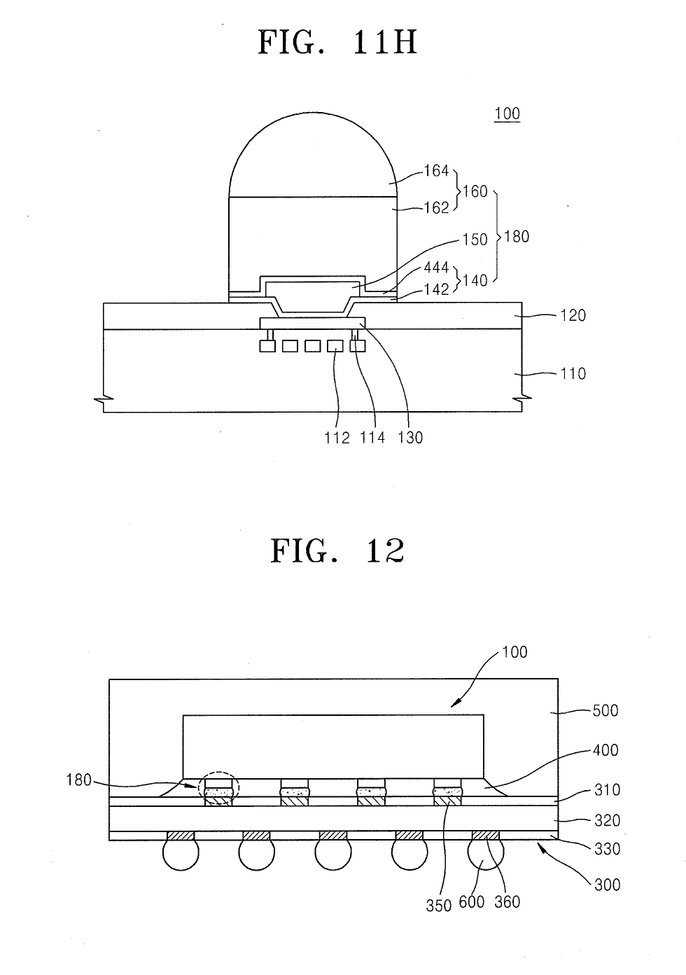

Passivation layer 120 may be formed on an upper surface of body portion 110 to cover and protect body portion 110, and may be formed of an insulating material such as photo-sensitive polyimide (PSPI). Passivation layer 120 may include an opening Oarea1 (see FIG. 11A) exposing the body portion 110.

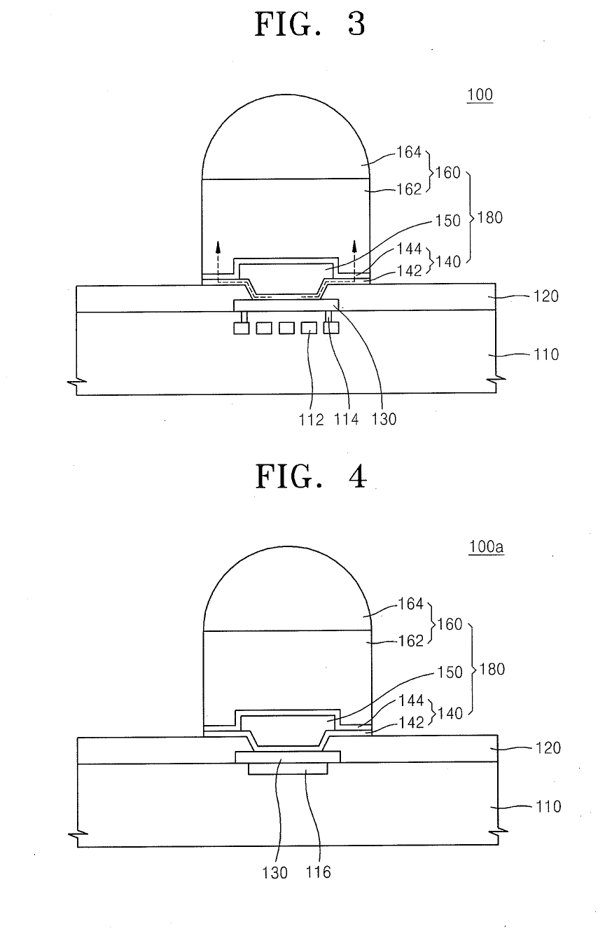

Bump structure 180 may be formed on an opening portion of passivation layer 120. In order to exchange signals with the semiconductor structures, bump structure 180 may be electrically connected to the semiconductor structures via a pad 130 (see FIG. 3) formed in the body portion 110 and the wiring lines. Bump structure 180 physically and/or electrically connects the semiconductor chip 100 and a mounting substrate, such as a printed circuit board (PCB), which is to be described later, to function as a moving path through which various signals are supplied from the outside and are transmitted to semiconductor chip 100.

Bump structures 180 may be arranged in a connection area IA of body portion 110 in a predetermined form, such as in rows as illustrated in FIG. 2, for example. For reference, the body portion 110 may be divided into a main area MA, including a cell area C and a peripheral area P, and a connection area IA in which bump structure 180 is arranged. Semiconductor structures may be arranged in cell area C, and peripheral circuits, such as circuits for driving the semiconductor structures, may be arranged in the peripheral area P. Peripheral circuits may also be arranged in the connection area IA, for example.

Connection terminals that receive an electrical signal from the outside (that is, from outside semiconductor chip 100) and transmit the same to the semiconductor structures may be concentrated in connection area IA, and wiring lines (not shown) arranged in the main area MA may be extended to connection area IA. In an exemplary embodiment in accordance with principles of inventive concepts, bump structure 180, which may operate as a connection terminal, and pads connected thereto may be arranged in two rows in connection area IA, and the wiring lines may be extended to connection area IA to be electrically connected to the pads. Connecting portions between the wiring lines and the pads may be referred to as rewiring lines.

Wiring lines may be excluded from connection area IA, and accordingly, wiring lines may be protected from damage while bump structure 180 is being formed. If connection terminals connecting to an external device and the pads that are electrically connected to the connection terminals are concentrated in the connection area IA, the connection area IA may also be referred to as a pad area.

In an exemplary embodiment in accordance with principles of inventive concepts, the connection area IA may be disposed as a center pad type in which pads are aligned in a line along a center portion of semiconductor chip 100. However, connection area IA is not limited to the center pad type. For example, connection area IA may be an edge pad type in which the connection area IA is disposed in two edge portions of semiconductor chip 100 and a cell area C and a peripheral area P are disposed between the two edge portions. Additionally, a portion of connection area IA may be a complex pad type in which a portion of pads is disposed in a center portion and another portion of pads is disposed in edge portions.

Bump structure 180 may be formed as an auxiliary element in main area MA, for example. Pads may also be disposed in main area MA. Pads arranged in main area MA may directly contact the wiring lines via vertical via contacts, for example. Pads formed in main area MA are selectively arranged, and, thus, main area MA is also referred to as a pseudo pad area. Pads disposed in main area MA may be arranged nonuniformly according to specific requirements or characteristics of the semiconductor structures inside semiconductor chip 100, such as the functional layout of semiconductor structures, for example.

In an exemplary embodiment in accordance with principles of inventive concepts, bump structure 180 may have a structure that accommodates, relieves, or mitigates, mechanical stress applied to the pads due to a difference in coefficient of thermal expansion (CTE) of the PCB and the semiconductor chip, thus reducing the likelihood of damage to pads or other structures, particularly during bonding or reflow processes. Additionally, bump structure 180 may allow pads to be disposed at any position on the semiconductor chip and the area of the bump structure 180 need not be the same as the area of the pad, thus enabling a reduction in pad size. The resultant free arrangement of pads and reduction in pad size associated with exemplary embodiments in accordance with principles of inventive concepts may contribute to a reduction in the total size of a semiconductor chip, in addition to increased reliability. Exemplary embodiments in accordance with principles of inventive concepts of bump structure 180 will be further described in the discussion related to FIGS. 3 through 10, below.

FIG. 2 is a perspective view illustrating a semiconductor chip 200 in accordance with principles of an exemplary embodiment of inventive concepts. Descriptions of elements that are the same as, or similar to, those of the embodiment described with reference to FIG. 1 will be simplified or omitted here for convenience of description.

Referring to FIG. 2, unlike the semiconductor chip 100 of FIG. 1, semiconductor chip 200 may include a bump structure 280 that is formed over the entire main area MA. Semiconductor chip 200 includes a body portion 210 and a passivation layer 220.

As described above with reference to FIG. 1, in an exemplary embodiment in accordance with principles of inventive concepts, because mechanical stress applied to bump structure 280 may be reduced, pads may be disposed anywhere on semiconductor chip 200. Accordingly, bump structure 280 may also be disposed anywhere on semiconductor chip 200. In an exemplary embodiment in accordance with principles of inventive concepts, a connection area need not be set aside in semiconductor chip 200, unlike the embodiment of FIG. 1 in which the connection area IA is distinguished from the main area MA.

According to an exemplary embodiment in accordance with principles of inventive concepts, a pad (not shown) may be disposed to directly contact a wiring line (not shown) in the main area MA via a vertical via contact, for example. Accordingly, bump structure 280 disposed on the pad may also be disposed in the main area MA. Referring to FIG. 2, bump structure 280 may be disposed only in a cell area C but it may also be disposed in a peripheral area P. Although bump structure 280 is arranged regularly in an array structure in FIG. 2, bump structure 280 may also be arranged irregularly, according to characteristic, such as layout, for example, of semiconductor structures in semiconductor chip 200.

If the pad and bump structure 280 are disposed in the cell area C, in which wiring lines are formed, in semiconductor chip 200 in an exemplary embodiment in accordance with principles of inventive concepts, an additional area need not be set aside as a connection area. As a result, the size of semiconductor chip 200 may be reduced by an amount roughly corresponding to the size of a connection area.

FIG. 3 is a cross-sectional view of a semiconductor chip 100 illustrating an exemplary embodiment in accordance with principles of inventive concepts of a bump structure such as described in the discussion related to FIG. 1 or FIG. 2. Semiconductor chip 100 may include a body portion 110, a passivation layer 120, a pad 130, and a bump structure 180. Body portion 110 may include a plurality of semiconductor structures (not shown) stacked on a substrate, and wiring lines 112 electrically connected to the semiconductor structures. The semiconductor structures formed in the body portion 110 may be semiconductor structures such as memory devices or logic devices, for example.

Wiring lines 112 may be disposed above the semiconductor structures, and an interlayer insulating layer (not shown) may be interposed between the wiring lines and the semiconductor structures. Wiring lines 112 may be disposed in a main area of body portion 110 as described above. Also as described above, wiring lines 112 may include power and ground lines in addition to signal lines.

Wiring lines 112 may be distributed in various layers in body portion 110, and various layers of wiring lines 112 may be connected to one another via a vertical via contact, for example. Wiring lines 112 illustrated in FIG. 3 may be in an uppermost wiring line layer among wiring lines arranged in various layers. Wiring lines 112 may be connected to pad 130 through a via contact 114 as illustrated in FIG. 3, for example.

As described above, passivation layer 120 may be an insulating layer and may be formed to cover the entire upper surface of body portion 110 in order to protect body portion 110. Passivation layer 120 may be a single layer or may include multiple layers. According to an exemplary embodiment in accordance with principles of inventive concepts, passivation layer 120 may be formed of photo-sensitive polyimide, for example. Passivation layer 120 may also include an opening Oarea1 11a (see FIG. 11A) exposing a portion of pad 130.

Pad 130 may be disposed in an opening portion of passivation layer 120 on body portion 110 and may be formed of a metal such as aluminum (Al) or copper (Cu), for example, but the material of the pad 130 is not limited thereto. Pad 130 may be of a single layer or may include multiple layers. Pad 130 may have a thickness of several μm, and have a surface area of 100*100 μm² or less, for example, but the size of pad 130 is not limited to such dimensions.

Pad 130 may be disposed in a connection area as illustrated in FIG. 1, or in the main area, according design parameters. As illustrated in FIG. 2, pad 130 may also be disposed in the main area of semiconductor chip 200 that does not include a connection area.

When a semiconductor chip is mounted on a PCB, a mechanical stress may be applied to pad 130 due to mismatch in CTE between the PCB and the semiconductor chip (for example, the CTE of a semiconductor chip may be smaller than that of a PCB). The pad and a lower portion below the pad may be damaged as a result of such CTE mismatch stress, thereby reducing system reliability. Such stress is mitigated in exemplary embodiments in accordance with principles of inventive concepts.

If a wiring line is disposed directly below a pad and the pad is connected to the wiring line through a via contact, the pad and the via contact may be damaged, thereby causing defects in a semiconductor device. Accordingly, a connection area in which the pad is disposed may be formed separately from the main area in which a wiring line is disposed, and the pad in the connection area may be connected to the rewiring line through a via contact, for example.

Bump structure 180 in an exemplary embodiment in accordance with principles of inventive concepts has a structure in which a stress applied to pad 130 is minimized, and thus, pad 130 may be disposed above wiring line 112, as illustrated in FIG. 2. Pad 130 may be connected to wiring line 112 through the via contact 114. Pad 130 may also be disposed in the connection area, as described in the discussion related to FIG. 1, and may be connected to wiring line 112 within the main area MA via a rewiring line.

In an exemplary embodiment in accordance with principles of inventive concepts bump structure 180 may include an under bump metal (UBM) 140, a buffer 150, and a bump 160.

The UBM 140 may include a lower UBM 142 and an upper UBM 144. The lower UBM 142 may be formed of titanium (Ti) or tungsten titanium (TiW), for example. The upper UBM 144 may be formed of Ti/Cu, for example. However, the lower UBM 142 and the upper UBM 144 may also be formed of materials other than those just described.

The lower UBM 142 may be formed on pad 130 exposed via an opening of the passivation layer 120, on side surfaces of the opening, and on an upper surface of passivation layer 120 around the opening, to have a thickness of, for example, about 500 nm. Lower UBM 142 may be formed to cover a lower side of buffer 150.

Upper UBM 144 may cover an upper surface and a lateral surface of buffer 150, and may be extended to an outer portion of lower UBM 142. Upper UBM 144 may also have a thickness of about 500 nm, for example. However, the thicknesses of the lower UBM 142 and the upper UBM 144 are not limited to the described thicknesses.

UBM 140 improves coupling force between pad 130 and bump 160 to thereby reduce contact resistance. UBM 140 may also function as a seed metal to form bump 160 using a plating method. Depending on the material of buffer 150, upper UBM 144 may be omitted. UBM 140 will be described in greater detail in the discussion related to FIGS. 11B and 11C.

Buffer 150 may be disposed on lower UBM 142 and formed to fill the opening of passivation layer 120. Buffer 150 may be extended to lower UBM 142 on the upper surface of the passivation layer 120, as illustrated in FIG. 3. Buffer 150 may have various structures; an exemplary embodiment of a structure in accordance with principles of inventive concepts will be described in greater detail in the discussion related to FIGS. 6 through 10.

Buffer 150 may be formed of a conductive material or an insulating material. Also, buffer 150 may be formed of a material that is capable of mitigating or absorbing stress applied to pad 130 by bump 160. For example, buffer 150 may be formed of an insulating material, such as silicon rubber or polymer, which is capable of mitigating the stress, for example. In FIG. 3, an arrow denotes a signal transfer path in a case when buffer 150 is formed of an insulating material.

Buffer 150 may be formed of a conductive material such as metal-epoxy, an anisotropic conductive film (ACF), or a rubber connector, for example. By a rubber connector is meant a silicon rubber in which, for example, a conductive line is formed. The conductive line may be formed of a fine metal wire or fine conductive particles, for example, and in this case, the upper UBM 144 may be omitted.

Buffer 150 may be formed using a printing method such as a roll-printing method or a stencil printing method and may have a thickness of 100 μm or less, for example. However, the thickness of the buffer 150 is not limited thereto, and the buffer 150 may have a thickness of 100 μm or greater, according to circumstances.

According to an exemplary embodiment in accordance with principles of inventive concepts, as buffer 150 is formed inside bump structure 180, stress applied to the pad may be mitigated or minimized, thereby preventing damage of the pad and the portion below the pad. Accordingly, in such case, the pad may be disposed on any position in the semiconductor chip, and thus on a wiring line of the main area. Because, in such a case, the pad may be disposed in the main area, an additional area for the pad such as a connection area is not necessary, thereby contributing to reduction in a chip size.

Bump 160 may include a metal filler 162 and a solder 164 formed on metal filler 162, for example. Metal filler 162 may be formed using an electro-plating process, and may be of a cylindrical shape. According to an exemplary embodiment in accordance with principles of inventive concepts, metal filler 162 may be a copper (Cu) filler, for example. However, the material of the metal filler 162 is not limited to Cu and may be formed of other materials, such as aluminum (Al), nickel (Ni), gold (Au), or an alloy of these. Metal filler 162 need not be of a cylindrical shape, but may be of another shape, such as a rectangular pillar or an oval pillar, for example.

Solder 164 may be formed of tin (Sn) and on metal filler 162. Alternatively, solder 164 may be formed of palladium (Pd), Ni, silver (Ag), lead (Pb), or an alloy of these, for example. Solder 164 may be formed to have a hemispheric shape using a reflow-process. However, according to the reflow-process, solder 164 may have a slightly different shape from a hemisphere. For example, solder 164 may be further extended to cover some of lateral portions of metal filler 162.

According to an exemplary embodiment in accordance with the principles of inventive concepts, metal filler 162 may be formed on UBM 140 by electroplating or electroless plating, and accordingly, a lower surface of metal filler 162 may have the same size as the upper surface of UBM 140. Thus, by adjusting a size of UBM 140, the size of metal filler 162 may be adjusted. That is, a bump including metal filler 162 is not limited within the opening through which the pad is exposed, but may be extended to some portions of passivation layer 120 on which UBM 140 is formed. Accordingly, as long as metal filler 162 of this exemplary embodiment is connected to pad 130 via UBM 140, metal filler 162 may be formed without regard to pad size, which may be considerably reduced. That is, reduction in pad size need not be limited by a large bump 180, as UBM 140 operates to link what may be a smaller pad 130 to a larger bump 180.

FIGS. 4 through 10 are cross-sectional views illustrating exemplary embodiments in accordance with principles of inventive concepts of semiconductor chip 100 described in the discussion related to FIG. 3. For convenience and clarity of description, descriptions described above with reference to FIG. 3 will be simplified or omitted.

Referring to FIG. 4, a semiconductor chip 100a including a pad 130 and a bump structure 180 has the same structure as semiconductor chip 100a of FIG. 3 except for the position of pad 130. That is, pad 130 of semiconductor chip 100a may be disposed in a connection area. Accordingly, pad 130 may be connected to a wiring line, not through a via contact, but through a rewiring line 116 in the exemplary embodiment in accordance with principles of inventive concepts of FIG.4. Referring to FIG. 4, rewiring line 116 contacts a lower surface of pad 130.

As is shown in this exemplary embodiment in accordance with principles of inventive concepts, bump structure 180 including a buffer may also be applied to a semiconductor chip structure including a connection area as that illustrated in FIG. 1. Also, when the bump structure 180 including a buffer is applied to a semiconductor chip structure including a connection area as illustrated in FIG. 1, bump structure 180 may mitigate a stress applied to the pad 130 to prevent damage of the pad 130 and the rewiring line 116. In addition, bump structure 180 may not be restricted by a size of the pad 130, and a measure of freedom in arranging bump structure 180 may therefore be provided. Accordingly, the size of pad 130 may be reduced, and also, the size of the bump structure 180 may be reduced. For example, the pad 130 may be formed to have a surface area of 100*100 μm² or smaller.

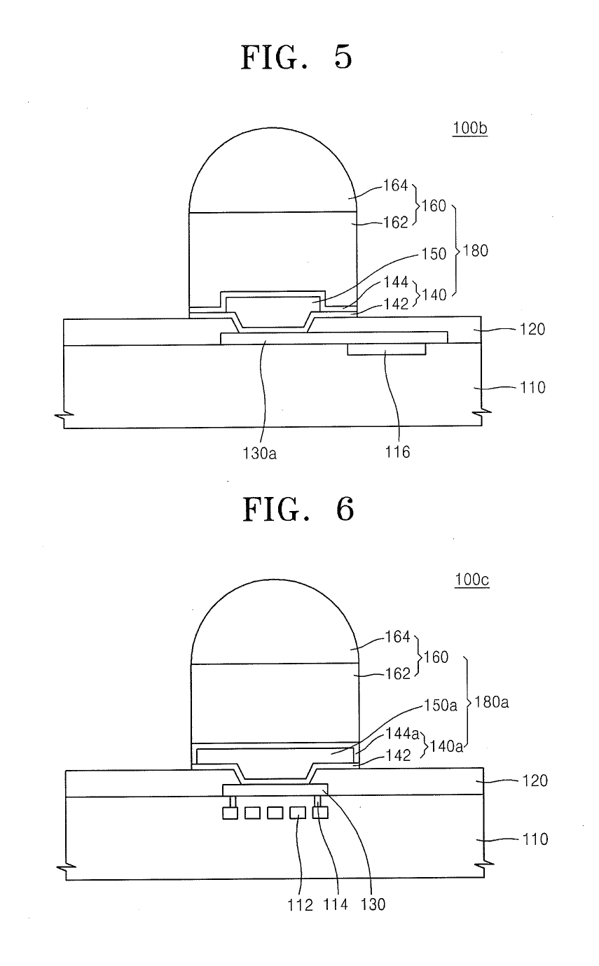

Referring to FIG. 5, an exemplary embodiment of a semiconductor chip 100b in accordance with principles of inventive concepts is similar to semiconductor chip 100a described in the discussion related to FIG. 4, only differing in terms of the structure of pad 130a and position of rewiring line 116. That is, pad 130a may be extended to a right side from an opening portion (see FIG. 11A). Also, the rewiring line 116 may be disposed, not below the opening, but below the extended portion of pad 130a. Because rewiring line 116 is disposed below the extended portion of pad 130a in an exemplary embodiment, the potential for damage due to mechanical stress may be further reduced. That is, when rewiring line 116 is used, mechanical stress in the area of pad 130a may be further reduced when rewiring line 116 contacts a portion of pad 130a away from the area of pad 130a where mechanical stress due to CTE mismatch is generated.

Referring to FIG. 6, an exemplary embodiment of a semiconductor chip 100c in accordance with principles of inventive concepts is similar to semiconductor chip 100 described in the discussion related to FIG. 3 but may differ in terms of structures of buffer 150a and upper UBM 144a. That is, in this exemplary embodiment, buffer 150a may be formed to extend over a lower UBM 142. Additionally, because buffer 150a is extended, upper UBM 144a may be formed to surround only an upper surface and a side surface of buffer 150a. However, as edge portions of lower UBM 142 and upper UBM 144a contact each other, a current path may be provided thereby. If buffer 150a is formed of a conductive material, lower UBM 142 and the upper UBM 144a do not have to contact each other, and upper UBM 144a does not have to be formed on buffer 150a.

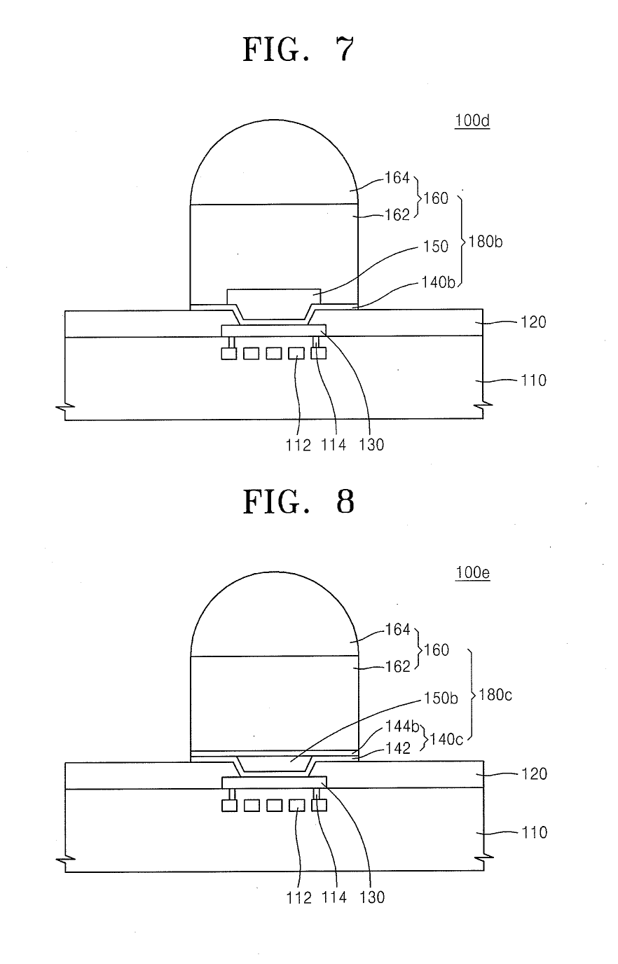

Referring to FIG. 7, in an exemplary embodiment of a semiconductor chip 100d in accordance with principles of inventive concepts is similar to semiconductor chip 100 described in the discussion related to FIG. 3 except that an upper UBM is not formed. That is, when a buffer 150a is formed of a conductive material, an upper UBM is not necessary; when forming a bump 160, a lower UBM 142 and a buffer 150 may function as a seed metal for electro-plating. Accordingly, an UBM may be formed of only a lower UBM 140b in such an exemplary embodiment.

An exemplary embodiments in accordance with principles of inventive concepts in which a buffer 150 of a bump structure is formed of a conductive material, an upper UBM 144 may be omitted. This may also apply to other embodiments as well.

Referring to FIG. 8, an exemplary embodiment of a semiconductor chip 100e in accordance with principles of inventive concepts is similar to semiconductor chip 100 described in the discussion related to FIG. 3 except that the structure of buffer 150b may differ, and accordingly, the structure of an upper UBM 144b may be different. That is, buffer 150b may be formed only on an opening portion (see FIG. 11A) of a passivation layer 120. Referring to FIG. 8, although an upper surface of the buffer 150b is illustrated to be on the same plane as an upper surface of an outer portion of a lower UBM 142, an upper surface of the buffer 150b may be lower than the upper surface of the outer portion of lower UBM 142, for example.

Because buffer 150b is formed only in an opening, upper UBM 144b may be almost horizontal. If the upper surface of buffer 150b is formed to be lower than the upper surface of the outer portion of lower UBM 142, a center portion of the upper UBM 144b may be concavely curved in a downward direction.

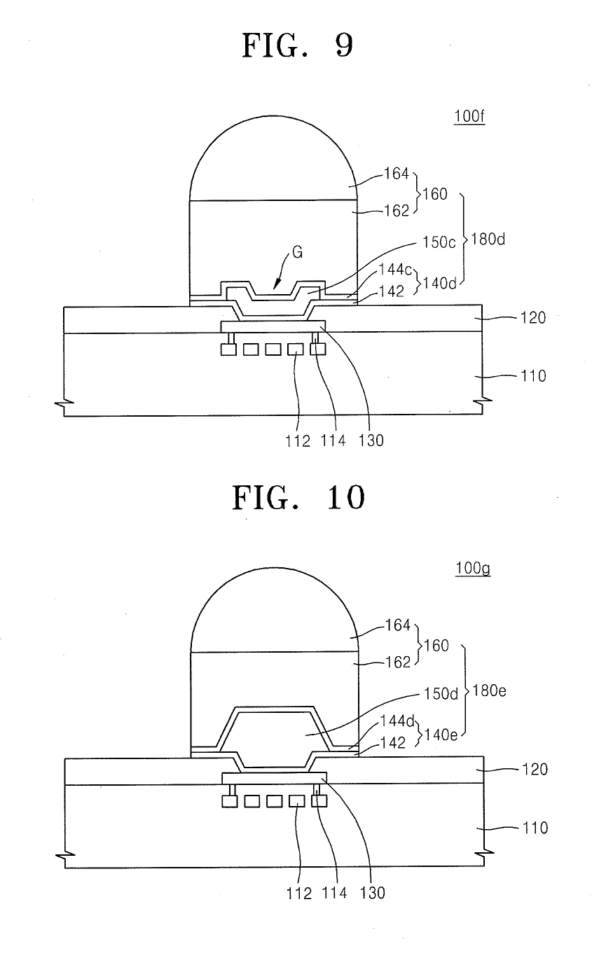

Referring to FIG. 9, an exemplary embodiment of a semiconductor chip 100f in accordance with principles of inventive concepts is similar to semiconductor chip 100 described the discussion related to FIG. 3, except that the structure of buffer 150c, and accordingly, the structure of upper UBM 144c may be different. That is, a center portion of buffer 150c may be concavely formed in a downward direction. Buffer 150c may have an overall substantially uniform thickness. For example, buffer 150c may have a substantially uniform thickness which is 100 μm or less.

As described above, buffer 150c may be formed using a printing method, and accordingly, buffer 150c may have a uniform thickness. When buffer 150c is formed to have a uniform thickness, a concave portion G may be formed in an opening portion as illustrated in FIG. 9.

Upper UBM 144c may be formed to surround upper and side surfaces of buffer 150c, and may be extended to an outer portion of lower UBM 142. Because buffer 150c has a concave faun, upper UBM 144c may have a concave center portion in conformity to the form of the upper surface of buffer 150c.

Referring to FIG. 10, an exemplary embodiment of a semiconductor chip 100g in accordance with principles of inventive concepts is similar to semiconductor chip 100 described in the discussion related to FIG. 3, except that the structure of buffer 150d may differ, and accordingly, the structure of upper UBM 144d may be different. That is, buffer 150d may be filled in an opening to be formed have a convex form in an upward direction. The convex form of buffer 150d is different from the convex form of buffer 150 of FIG. 3. That is, while the side surface of buffer 150 is vertical to the upper surface thereof, a side surface of buffer 150d according to this exemplary embodiment may be inclined with respect to the upper surface thereof. The thickness of buffer 150d of this exemplary embodiment may be thicker than that of buffer 150 of FIG. 3.

As buffer 150d having a convex structure that is inclined at an angle with respect to the upper surface thereof is formed, upper UBM 144d may also be formed to have a convex structure that is inclined at an angle in conformity to the upper surface of buffer 150d. However, upper UBM 144d may be extended to an outer portion of lower UBM 142 to contact the lower UBM 142.

FIGS. 11A through 11H are cross-sectional views illustrating a an exemplary method in accordance with principles of inventive concepts of manufacturing semiconductor chip of FIG. 3.

Referring to FIG. 11A, a pad 130 is formed on a body portion 110, and a passivation layer 120 is formed to cover an upper surface of body portion 110 and the pad 130. After forming the passivation layer 120, a first opening Oarea1 exposing a portion of pad 130 is formed.

As described above with reference to FIG. 1, a plurality of semiconductor structures (not shown) and wiring lines may be formed in the body portion 110. Among the wiring lines, an uppermost wiring line 112 is illustrated. The wiring line 112 may be electrically connected to pad 130 through a via contact 114.

Referring to FIG. 11B, a first seed metal 142a is formed on upper and side surfaces of passivation layer 120 and an upper surface of pad 130 exposed through the first opening Oarea1. The first seed metal 142a may be Ti or TiW, for example, and may be formed to have a thickness of about 500 nm by using a sputtering method or electroless plating. However, the material and method for forming the first seed metal 142a, and the thickness of the first seed metal 142a are not limited to examples described above.

Referring to FIG. 11C, a buffer 150 is formed in a portion of first seed metal 142a, corresponding to first opening Oarea1. Buffer 150 may be formed of a conductive material or an insulating material. For example, when buffer 150 is formed of an insulating material, buffer 150 may be formed of a polymer such as an epoxy resin; when the buffer 150 is formed of a conductive material, it may be formed of a metal-epoxy or a rubber connector, etc.

Buffer 150 may be formed using a printing method such as a roll-printing method or a stencil printing method with various structures as shown in FIGS. 3, 6, and 8 through 10. However, the structure of buffer 150 is not limited to the structures illustrated in these drawings.

Referring to FIG. 11D, a seed metal 144e is formed on an upper surface of first seed metal 142a and upper and side surfaces of buffer 150. Second seed metal 144e may be Ti/Cu, and may be formed by sputtering or electroless plating and to a thickness of about 500 nm, for example. However, the material and method for forming second seed metal 144e, and the thickness of second seed metal 144e are not limited as described above.

As the second seed metal 144e is formed, buffer 150 may be completely surrounded by first seed metal 142a and second seed metal 144e. Also, second seed metal 144e may contact a portion of first seed metal 142a where buffer 150 is not formed.

When buffer 150 is foamed of a conductive material, second seed metal 144e may be omitted. However, to reinforce the function of a seed metal, second seed metal 144e may be formed also when buffer 150 is formed of a conductive material.

Referring to FIG. 11E, a photoresist (PR) pattern 170 having a second opening Oarea2 that exposes a portion of second seed metal 144e where buffer 150 is formed, is formed. Second opening Oarea2 may be formed in consideration of a size of a bump structure that is to be formed later. For example, second opening Oarea2 may be formed to expose a portion of second seed metal 144e where buffer 150 is formed and up to a portion of second seed metal 144e formed on passivation layer 120 in an outer portion of second seed metal 144e.

Referring to FIG. 11F, a metal filler 162 that fills second opening Oarea2 and a tin layer 164a on metal filler 162 are formed sequentially. Metal filler 162 and tin layer 164a may be formed using first and second seed metals 142a and 144e by using electro-plating, for example.

Metal filler 162 may be a copper (Cu) filler, for example, however, the material of the metal filler 162 is not limited to Cu. According to circumstances, tin layer 164a may contain a small amount of Pd, Ag, Ni, or Pb. Tin layer 164a may be a semicircle and may extend to some portions of an upper surface of the PR pattern 170 as illustrated in FIG. 11F, for example.

Referring to FIG. 11G, the PR pattern 170 may be removed by ashing or stripping, for example. Next, exposed portions of second seed metal 144e and first seed metal 142a are removed by etching, using metal filler 162 as a mask. By etching second seed metal 144e and first seed metal 142a, a UBM 140 including a lower UBM 142 and an upper UBM 144 may be formed.

As portions of second seed metal 144e and first seed metal 142a may be removed by using metal filler 162 as a mask, for example. Side surfaces of lower UBM 142 and upper UBM 144 may be on the same plane as a side of metal filler 162.

Referring to FIG. 11H, a reflow process may be performed to form solder 164 on metal filler 162. Due to surface tension occurring during the reflow process, solder 164 having a hemispheric form may be formed on an upper surface of metal filer 162. As solder 164 is formed based on tin layer 164a, solder 164 is a tin solder. If tin layer 164a contains lead, the solder 164 may also contain lead.

Through the reflow process, bump 160 including metal filler 162 and solder 164 may be completed. Also, semiconductor chip 100 of FIG. 3 may be completed.

Semiconductor chips manufactured in this exemplary manner in accordance with principles and concepts may be mounted on a main board such as a PCB using a flip-chip technique by employing bump structure 180.

FIG. 12 is a cross-sectional view illustrating an exemplary embodiment of a flip-chip package in accordance with principles of inventive concepts.

Referring to FIG. 12, the flip-chip package may include: a semiconductor chip 100, a main board 300, an underfill 400, an encapsulation member 500, and an external connection terminal 600, for example.

Semiconductor chip 100 may be a semiconductor chip 100 including the bump structure 180 having the structure described in the discussion related to FIG. 3, for example. Semiconductor chips 100a, 100b, 100c, 100d, 100e, 100f, and 100g described in the discussions related to FIGS. 4 through 10, may be applied to the flip-chip package. Although not shown in the drawings, semiconductor chips including a bump structure of various examples and other equivalent examples and a flip-chip package including the semiconductor chips may be included in the technical spirit and scope of the inventive concept.

Main board 300 may be a PCB, a glass substrate, or a flexible film, for example, and may include an upper connection portion 310, a body 320, and a lower connection portion 330.

Upper contact pad 350 may be disposed in upper connection portion 310, and bump structure 180 of semiconductor chip 100 may be coupled to upper contact pad 350. The upper connection portion 310 may include a photo solder resist (PSR) or a solder resist. A wiring circuit (not shown) for electrically connecting upper contact pad 350 to a lower connection pad 360 of lower connection portion 330 may be disposed in body 320. The wiring circuit may include a through-hole via, for example. Lower contact pad 360 may be disposed in lower connection portion 330, and an external connection terminal 600 may be coupled to lower contact pad 360. Lower connection portion 330 may also include a photo solder resist or a solder resist.

Underfill 400 may fill space between semiconductor chip 100 and main board 300 to protect bump structure 180, for example, from an external impact. When a packaging operation is performed using a molded underfill (MUF) process, underfill 400 may be omitted.

Encapsulation member 500 encapsulates semiconductor chip 100 to protect semiconductor chip 100 from an external physical and/or chemical impact. Encapsulation member 500 may be formed of an epoxy resin such as an epoxy molding compound (EMC), for example. When encapsulation member 500 is formed using a MUF process, underfill 400 may be omitted as described above.

External connection terminal 600 may be coupled to lower connection terminal 360 to couple a flip-chip package to an external device. External connection terminal 600 may be a solder-ball. The external device to which the flip-chip package is coupled may be not only a logic circuit or a memory module to which the semiconductor chip 100 is applied but also a system including the logic circuit or the memory module. Examples of the system include various electronic devices such as a computer system, a mobile phone, and a MP3 player, for example.

FIG. 13 is a block diagram of a memory card 7000 including a flip-chip package according to principles of inventive concepts.

Referring to FIG. 13, a controller 7100 and a memory 7200 may be arranged to exchange an electrical signal with each other in memory card 700. For example, when controller 7100 gives a command, memory 7200 may transmit data. Controller 7100 and/or memory 7200 may include a flip-chip package according to an exemplary embodiment in accordance with principles of inventive concepts. Memory 7200 may include a memory array (not shown) or a memory array bank (not shown).

Memory card 700 may be used in a memory device, such as a memory stick card, a smart media card (SM), a secure digital (SD), a mini secure digital card (mini SD), or a multi media card (MMC), for example.

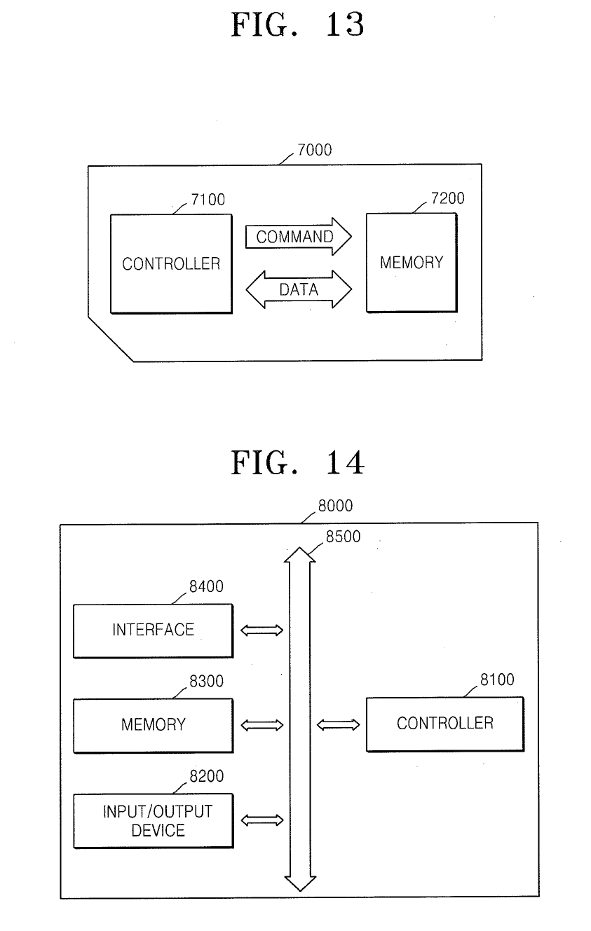

FIG. 14 is a block diagram of an electronic system 8000 including a flip-chip package in accordance with principles of inventive concepts.

Referring to FIG. 14, electronic system 8000 may include a controller 8100, an input/output device 8200, a memory 8300, and an interface 8400. Electronic system 8000 may be a mobile system or a system for transmitting or receiving information, for example. The mobile system may be, for example, a personal digital assistant (PDA), a portable computer, a web tablet, a wireless phone, a mobile phone, a digital music player, or a memory card.

Controller 8100 may execute programs and control electronic system 8000. Controller 8100 may be, for example, a microprocessor, a digital signal processor, a microcontroller, or other control device, for example. Input/output device 8200 may be used in inputting or outputting data of the electronic system 8000.

Electronic system 8000 may be connected to an external device such as a personal computer or a network via input/output device 8200 to exchange data with the external device. The input/output device 8200 may be, for example, a keypad, a keyboard, or a display. The memory 8300 may store codes and/or data for operating the controller 8100 and/or data processed using controller 8100. Controller 8100 and memory 8300 may include a flip-chip package according to an exemplary embodiment in accordance with principles of inventive concepts. Interface 8400 may be a data transmission path between electronic system 8000 and other external device. Controller 8100, input/output device 8200, memory 8300, and interface 8400 may communicate with one another via a bus 8500.

Electronic system 8000 may be used in mobile phones, MP3 players, navigation devices, portable multimedia players (PMP), solid state disks (SSD), household appliances, or other systems.

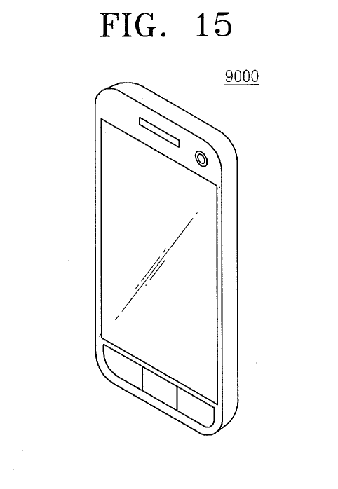

FIG. 15 is a block diagram of an electronic device to which a flip-chip package in accordance with principles of inventive concepts may be applied.

FIG. 15 illustrates an example in which electronic system 8000 of FIG. 14 is applied to a mobile phone 9000. In addition, electronic system 8000 of FIG. 14 may be applied to portable laptop computers, MP3 players, navigation devices, solid state disks (SSD), automobiles, or household appliances.

While the inventive concept has been shown and described with reference to exemplary embodiments thereof, it will be understood that various changes in form and details may be made therein without departing from the spirit and scope of the following claims.

What is claimed is:

1. A semiconductor chip comprising:
a body portion inside which wiring lines are formed;
a pad that is formed on the body portion and is electrically connected to the wiring lines;
a passivation layer covering the body portion and the pad and having an opening exposing a portion of the pad;
a buffer that mitigates stress applied to the pad disposed within the opening; and
a bump that is formed to cover the buffer and is electrically connected to the pad.

2. The semiconductor chip of claim 1, wherein the buffer comprises a conductive material.

3. The semiconductor chip of claim 1, wherein the bump is extended to the passivation layer around the opening.

4. The semiconductor chip of claim 1, further comprising an under bump metal (UBM) positioned between the bump and passivation layer and that extends at least to the perimeter of the buffer.

5. The semiconductor chip of claim 1, further comprising a UBM formed on the pad,
wherein a side of the bump and the UBM are on the same plane.

6. The semiconductor chip of claim 1, wherein the buffer is formed inside the opening and on portions of the passivation layer around the opening.

7. The semiconductor chip of claim 1, wherein the buffer comprises one of a first type buffer having a concave portion corresponding to the opening, a second type buffer having a flat upper surface, and a third type buffer having an upper surface protruding in an upward direction.

8. The semiconductor chip of claim 7, wherein a protruding portion of the third type buffer is vertical to or inclined with respect to a horizontal surface.

9. The semiconductor chip of claim 1, wherein the bump comprises a metal filler and a solder formed on the metal filler.

10. The semiconductor chip of claim 1, wherein the body portion comprises an uppermost wiring layer disposed below the pad, and
the pad is electrically connected to the uppermost wiring layer through a via contact.

11. The semiconductor chip of claim 1, wherein the pad may be disposed at any position on the body portion.

12. A flip-chip package comprising:
a main board in which a circuit pattern is formed;
a semiconductor chip of claim 1 that is mounted on a first surface of the main board in a flip-chip bonding method;
an encapsulation member encapsulating the semiconductor chip; and
an external connection terminal formed on a second surface of the main board which is opposite to the first surface of the main board.

13. The flip-chip package of claim 12, wherein the bump is extended to the passivation layer around the opening, and
the buffer is formed either only within the opening.

14. The flip-chip package of claim 13, wherein the body portion comprises an uppermost wiring layer disposed below the pad, and
the pad is electrically connected to the uppermost wiring layer through a via contact.

15. A flip-chip package comprising:
a semiconductor chip comprising a pad, wherein a portion of the pad is exposed via an opening of a passivation layer;
a bump structure comprising a buffer that mitigates a stress applied to the pad, wherein the bump structure is formed on the pad and on the passivation layer around the opening;
a main board in which a circuit pattern is formed, wherein the semiconductor chip is mounted on a first surface of the main board via the bump structure in a flip-chip bonding method;
an encapsulation member encapsulating the semiconductor chip; and
a connection terminal that is formed on a second surface of the main board which is opposite to the first surface of the main board.

16. A semiconductor chip comprising:
a body portion inside which wiring lines are formed;
a pad that is formed on the body portion and is electrically connected to the wiring lines;
a passivation layer covering the body portion and the pad, the passivation layer having an opening exposing at least a part of the pad;
a stress-relief buffer disposed in the opening; and
under bump metal positioned between the buffer and the pad to link a pad and bump of different cross-sections.

17. The semiconductor chip of claim 16, wherein a wiring line is connected to a pad through a vertical via.

18. The semiconductor chip of claim 16, wherein a lower surface of a pad contacts a rewiring line that contacts a wiring line.

19. The semiconductor chip of claim 18, wherein the pad is located within a connection area of the chip.

20. The semiconductor chip of claim 17, wherein the pad is located in a main area of the chip.
